(19) United States
(12) Patent Application Publication
(10) Pub. No.: US 2017/0162366 A1
(43) Pub. Date: Jun. 8, 2017

(54) FILM FORMING APPARATUS, RECORDING MEDIUM, AND FILM FORMING METHOD

(71) Applicant: ASM IP Holding B.V., Almere (NL)

(72) Inventor: Ippei YANAGISAWA, Sagamihara-shi (JP)

(73) Assignee: ASM IP Holding B.V., Almere (NL)

(21) Appl. No.: 14/962,558

(22) Filed: Dec. 8, 2015

(51) Int. Cl. H01J 37/32; C23C 16/52; C23C 16/44; C23C 16/455; C23C 16/509

(52) U.S. Cl. CPC H01J 37/3244; H01J 37/32568; H01J 37/32357; H01J 37/32449; C23C 16/45559; C23C 16/509; H01J 37/32862; C23C 16/4405; C23C 16/52; H01J 2237/327; H01J 2237/3321; H01J 2237/3323

(57) ABSTRACT

A film forming apparatus includes a lower electrode, an upper electrode provided above and in opposition to the lower electrode and having a plurality of openings, a transport tube which provides a passage extending generally in a vertical direction and connecting to a space above the upper electrode, a gas supply line connected to a side surface of the transport tube and providing a passage communicating with a space in the transport tube, and a gas diffuser gate valve connected to a portion of the side surface of the transport tube at a position lower in the vertical direction than the position at which the gas supply line is connected, wherein the gas diffuser gate valve has a diffusion plate which blocks part of the space in the transport tube.

### BACKGROUND OF THE INVENTION

Field of the Invention

The present invention relates to a film forming apparatus used to perform film forming on a substrate and to a recording medium and a film forming method.

Background Art

U.S. Pat. No. 5,788,778 discloses a film forming apparatus having a susceptor functioning as a lower electrode and a shower head functioning as an upper electrode. When a material gas is supplied into a space above the shower head, the material gas is supplied to a substrate on the lower electrode through openings in the shower head.

For example, from the viewpoint of improving the yield of an LSI while making the LSI finer, there is a demand for providing an interlayer insulating film (e.g., a low-k film) or the like in thin film form and improving the in-plane uniformity of the film. In a case where a nonuniform gas is supplied into a chamber in which film forming is performed, however, a sloped film is formed or a particular portion of a thin film is relatively increased or reduced in thickness.

### SUMMARY OF THE INVENTION

In view of the above-described problem, an object of the present invention is to provide a film forming apparatus capable of carrying out film forming with high film thickness uniformity in the substrate surface, a recording medium and a film forming method.

The features and advantages of the present invention may be summarized as follows.

According to one aspect of the present invention, a film forming apparatus includes a lower electrode, an upper electrode provided above and in opposition to the lower electrode and having a plurality of openings, a transport tube which provides a passage extending generally in a vertical direction and connecting to a space above the upper electrode, a gas supply line connected to a side surface of the transport tube and providing a passage communicating with a space in the transport tube, and a gas diffuser gate valve connected to a portion of the side surface of the transport tube at a position lower in the vertical direction than the position at which the gas supply line is connected. The gas diffuser gate valve has a diffusion plate which blocks part of the space in the transport tube.

According to another aspect of the present invention, a computer-readable recording medium on which a program is recorded and which is readable with a computer, the program causing the computer to execute a film forming step including supplying a gas into a transport tube from a gas supply line connected to a side surface of the transport tube in which a passage extending generally in a vertical direction is provided, diffusing the gas by setting in the transport tube a diffusion plate blocking part of a space in the transport tube, and thereafter supplying the gas to a substrate on a lower electrode below an upper electrode through openings in the upper electrode, a chamber cleaning step of cleaning a chamber surrounding the lower electrode by supplying a gas into the transport tube while setting the diffusion plate out of the transport tube, and a diffusion plate cleaning step of cleaning the diffusion plate by supplying a gas into the transport tube while setting the diffusion plate in the transport tube.

According to another aspect of the present invention, a film forming method includes a film forming step including supplying a gas into a transport tube from a gas supply line connected to a side surface of the transport tube in which a passage extending generally in a vertical direction is provided, diffusing the gas by setting in the transport tube a diffusion plate blocking part of a space in the transport tube, and thereafter supplying the gas to a substrate on a lower electrode through openings in an upper electrode.

Other and further objects, features and advantages of the invention will appear more fully from the following description.

### BRIEF DESCRIPTION OF THE DRAWINGS

FIG. 1 is sectional view of a film forming apparatus according to a first embodiment;

FIG. 2 is an enlarged diagram of the gas diffuser gate valve and the RPU gate valve;

FIG. 3 is a plan view of a portion including the diffusion plate;

FIG. 4 is a bottom view of a portion including the diffusion plate;

FIG. 5 is a sectional view of a portion of the diffusion plate;

FIG. 6 shows holes which are not curved as viewed in section;

FIG. 7 is a plan view of a portion including the blocking plate;

FIG. 8 is a block diagram of the components including the control unit;

FIG. 9 is a flow chart;

FIG. 10 is a sectional view of the film forming apparatus operating to execute the chamber cleaning step;

FIG. 11 is a sectional view of the film forming apparatus operating to execute the diffusion plate cleaning step;

FIG. 12 is a table;

FIG. 13 is a sectional v of a film forming apparatus according to a comparative example;

FIG. 14 is a sectional view of a gas diffuser gate valve and other components of a film forming apparatus according to the second embodiment;

FIG. 15A is a plan view of the diffusion plate; and

FIG. 15B is a plan view of the auxiliary diffusion plate.

### DETAILED DESCRIPTION OF THE PREFERRED EMBODIMENTS

A film forming apparatus, a recording medium and a film forming method according to an embodiment of the present invention will be described with reference to the drawings. Components identical or corresponding to each other are indicated by the same reference characters and repeated description of them is avoided in some eases.

### First Embodiment

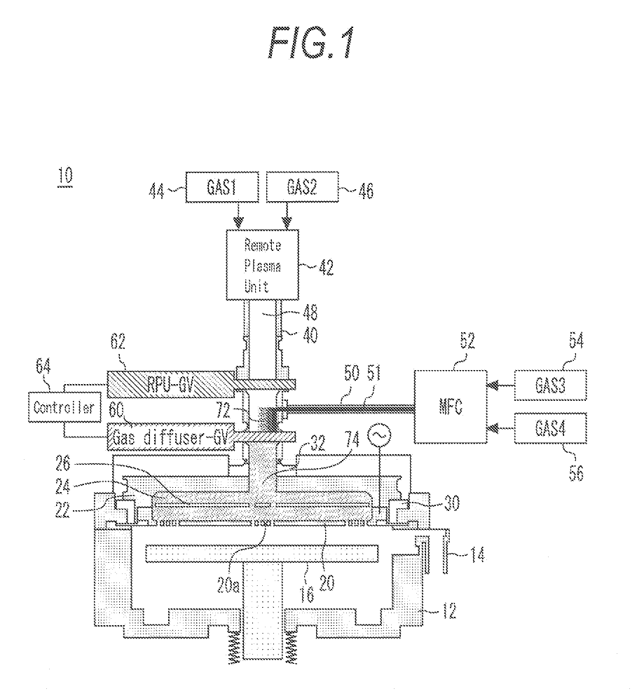

FIG. 1 is a sectional view of a film forming apparatus 10 according to a first embodiment of the present invention. The film forming apparatus 10 is provided with a chamber 12. An exhaust part 14 for discharging a gas in the chamber 12 is connected to a side surface of the chamber 12. A lower electrode 16 formed of a susceptor is provided in the chamber 12. An upper electrode 20 opposed to the lower electrode 16 is provided above the lower electrode 16. A plurality of openings 20a are formed in the upper electrode 20. The upper electrode 20 is referred to as a shower head or an RF plate as occasion arises. Alternating-current power is applied to the upper electrode 20 to generate plasma between the upper electrode 20 and the lower electrode 16, thereby carrying out film forming. A gas used for film forming spreads radially on the lower electrode 16 as viewed in plan, is received in an exhaust duct provided so as to surround the lower electrode 16, and is finally discharged from the exhaust part 14.

A fixed top plate 22 is provided above the upper electrode 20. A space existing above the upper electrode 20 is a space 24 enclosed with the upper electrode 20 and the fixed top plate 22. The space 24 has a width substantially equal to the width of the lower electrode 16, as shown in FIG. 1. The length of the space 24 in a lateral direction is larger than the length of the space 24 in the vertical direction. The area of the space 24 as viewed in plan is substantially equal to the area of the lower electrode 16.

A diffusing part 26 is provided in the space 24. The diffusing part 26 is a plate having openings. An insulating part 30 is provided between the upper electrode 20 and the chamber 12 and between the fixed top plate 22 and the chamber 12 to insulate the chamber 12 from the upper electrode 20 and the fixed top plate 22. The insulating part 30 functions as the above-described exhaust duct. In FIG. 1, a simplified expression of the exhaust duct is made.

A transport tube 40 is provided above the fixed top plate 22. An insulating part 32 for insulating the transport tube 40 and the fixed top plate 22 from each other is provided between the transport tube 40 and the fixed top plate 22. A passage 48 extending generally in the vertical direction and communicating with the space 24 above the upper electrode 20 is provided by means of the transport tube 40. The passage 48 connects to a center of the space 24 as viewed in plan. In other words, the passage 48 is right above a center of the lower electrode 16.

A remote plasma unit 42 is provided on an upper end of the transport tube 40. The remote plasma unit 42 causes a gas to be in a plasma state. Gas sources 44 and 46 are connected to the remote plasma unit 42. The gas sources 44 and 46 are for supplying a cleaning gas used to clean the chamber 12 and other components. When a gas is supplied from the gas source 44 or 46 into the remote plasma unit 42, reactive species are produced in the remote plasma unit 42. These reactive species are used for cleaning of the chamber 12 and other components.

A gas supply line 50 is connected to a side surface of the transport tube 40. A passage 51 communicating with the space in the transport tube 40 is provided by means of the gas supply line 50. The gas supply line 50 is connected to the transport tube 40 substantially perpendicularly to the same. That is, the gas supply line 50 is a tube extending generally horizontally.

A mass flow controller (MFC) 52 is connected to the gas supply line 50. Gas sources 54 and 56 are connected to the MFC 52. The gas sources 54 and 56 are for supplying a material gas used for film forming. Gases from the gas sources 54 and 56 are provided into the passage 51 while being pressure controlled by the MFC 52. The gases move generally horizontally in the passage 51 to reach the passage 48 in the transport tube 40.

A gas diffuser gate valve 60 is connected to a side surface of the transport tube 40. More specifically, the gas diffuser gate valve 60 is connected at a position in the side surface of the transport tube 40 lower in the vertical direction than the position at which the gas supply line 50 is connected. The gas diffuser gate valve 60 has a function to supply into the space 24 above the upper electrode 20 the material gas supplied into the passage 48 in the transport tube 40 while diffusing the material gas.

A remote plasma unit (RPU) gate valve 62 is connected to a side surface of the transport tube 40. More specifically, the RPU gate valve 62 is connected at a position in the side surface of the transport tube 40 higher in the vertical direction than the position at which the gas supply line 50 is connected. The RPU gate valve 62 is provided for the purpose of preventing mixing of the cleaning gas with the material gas by shutting off the remote plasma unit 42 and the chamber 12 from each other.

A control unit 64 is connected to the gas diffuser gate valve 60 and to the RPU gate valve 62. The control unit 64 controls opening/closing of the gas diffuser gate valve 60 and to the RPU gate valve 62.

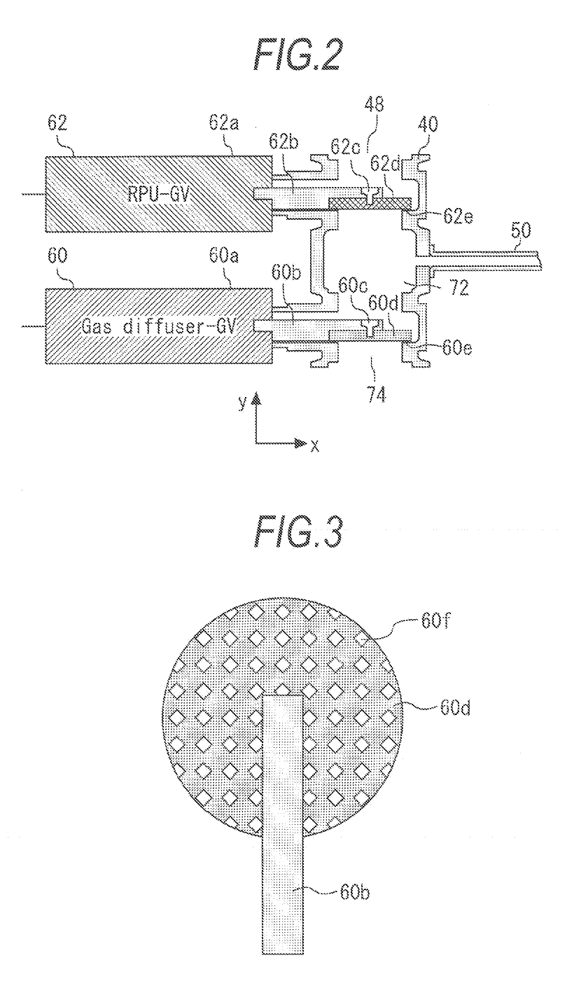

FIG. 2 is an enlarged diagram of the gas diffuser gate valve 60 and the RPU gate valve 62. The gas diffuser gate valve 60 has a drive device 60a, a shaft 60b moved by the drive device 60a, a fixing part 60c provided on a distal end portion of the shaft 60b, a diffusion plate 60d attached to the shaft 60b by the fixing part 60c, and an O-ring 60e attached to the diffusion plate 60d. The diffusion plate 60d is a plate with which part of the passage 48 is closed. That is, the gas diffuser gate valve 60 has the diffusion plate 60d that blocks part of the space in the transport tube 40.

The drive device 60a moves the shaft 60b in an x-positive/negative direction and in a y-positive/negative direction to put the diffusion plate 60d in the transport tube 40 or retract the diffusion plate 60d from the transport tube 40. FIG. 2 shows a state where the diffusion plate 60d is put in the transport tube 40. In this state, only the O-ring 60e in the component parts of the gas diffuser gate valve 60 is in contact with the transport tube 40, thereby avoiding the generation of dust due to “metal touch” which is, for example, contact between the diffusion plate 60d and the transport tube 40.

FIG. 3 is a plan view of a portion including the diffusion plate 60d. The shaft 60b exists above the diffusion plate 60d. The diffusion plate 60d is held by the shaft 60b. A plurality of holes 60f are formed in the diffusion plate 60d. The plurality of holes 60f are formed through the diffusion plate 60d in the thickness direction. It is preferable to form the plurality of holes 60f at a constant density. However, the present invention is not limited to this.

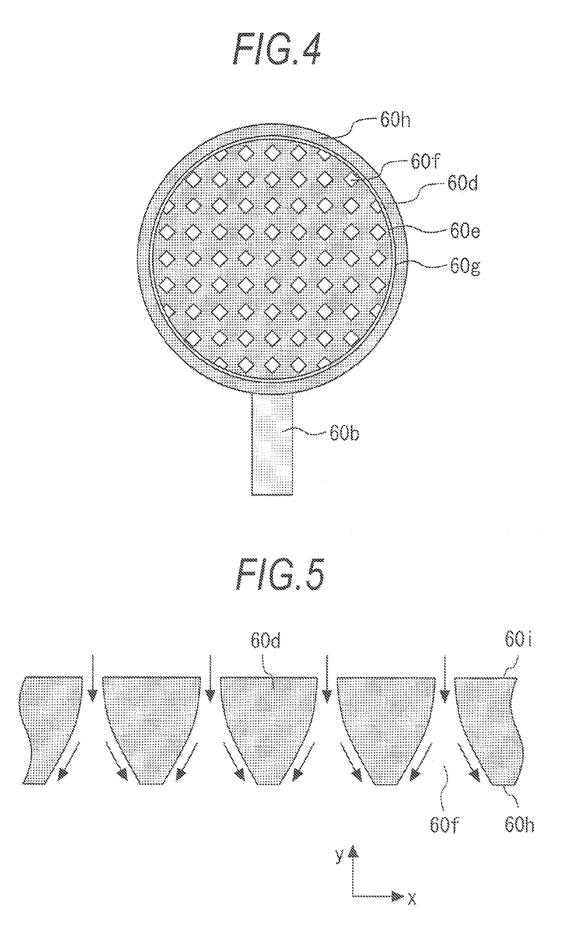

FIG. 4 is a bottom view of a portion including the diffusion, plate 60d. An annular groove 60g is formed in a lower surface 60h of the diffusion plate 60d. The O-ring 60e is set in the groove 60g. The O-ring 60e contacts the transport tube 40.

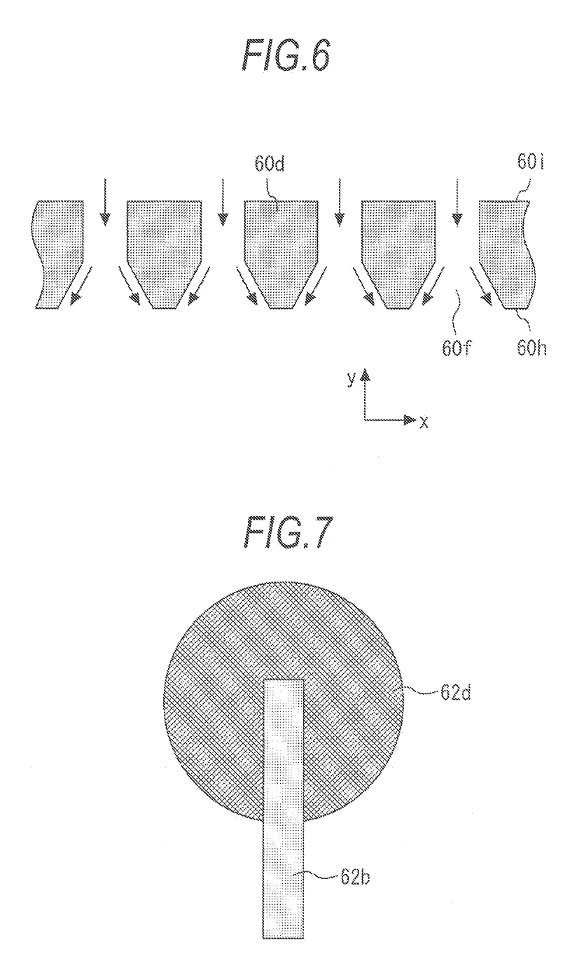

FIG. 5 is a sectional view of a portion of the diffusion plate 60d. The width of each of the plurality of holes 60f in the lower surface 60h of the diffusion plate 60d is larger than the width of the hole in an upper surface 60i of the diffusion plate 60d. Each of the plurality of holes 60f has the shape of a horn as viewed in section such that its opening width is larger at the lower surface side. Because of restrictions on techniques for machining, it is difficult to form the holes in horn shape. Therefore holes having a section such as shown in FIG. 6 may alternatively be formed. FIG. 6 shows holes 60f which are not curved as viewed in section but are larger in opening width at the lower surface 60h side of the diffusion plate 60d than at the upper surface 60i side. The holes 60f having the sectional shape shown in FIG. 6 are easier to manufacture than the holes 60f shown in FIG. 5.

Referring back to FIG. 2, the RPU gate valve 62 has a drive device 62a, a shaft 62b moved by the drive device 62a, a fixing part 62c provided on a distal end portion of the shaft 62b, a blocking plate 62d attached to the shaft 62b by the fixing part 62c, and an O-ring 62e attached to the blocking plate 62d. The blocking plate 62d is a plate with which the space in the transport tube 40 is blocked.

The drive device 62a moves the shaft 62b in an x-positive/negative direction and in a y-positive/negative direction to put the blocking plate 62d in the transport tube 40 or retract the blocking plate 62d from the transport tube 40. FIG. 2 shows a state where the blocking plate 62d is put in the transport tube 40. In this state, only the O-ring 62e in the component parts of the RPU gate valve 62 is in contact with the transport tube 40, thereby avoiding the generation of dust due to “metal touch” which is, for example, contact between the blocking plate 62d and the transport tube 40.

FIG. 7 is a plan view of a portion including the blocking plate 62d. The blocking plate 62d is one plate having no holes. A groove is formed in a lower surface of the blocking plate 62d. The O-ring 62e is set in the groove.

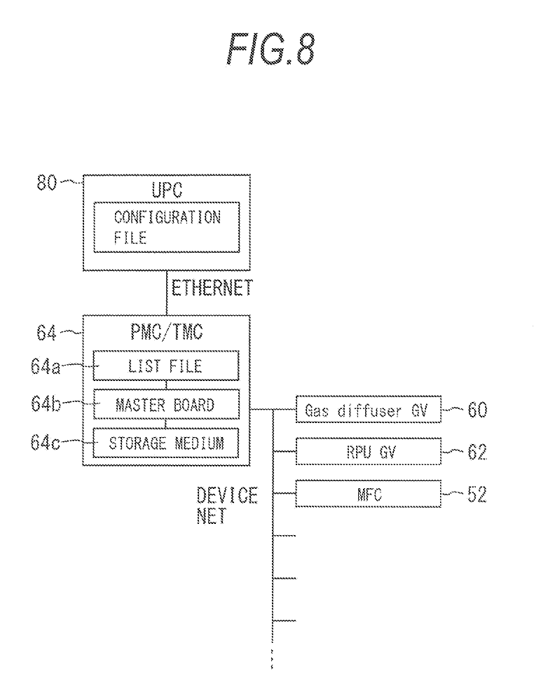

FIG. 8 is a block diagram of some of the components including the control unit 64. The control unit 64 is constituted by a module controller. In a UPC 80, a processing recipe, system parameters, etc., are stored. The control unit 64 controls opening/closing of the gas diffuser gate valve 60, opening/closing of the RPU gate valve 62 and the operation of the MFC 52 according to commands from the UPC 80. The control unit 64 also controls certain ones of the other components, e.g., the remote plasma unit 42 and the lower electrode 16.

The control unit 64 has a list file 64a in which the gas diffuser gate valve 60, the RPU gate valve 62 and the MFC 52 to be controlled are described. A, master board 64b controls the devices described in the list file 64a on the basis of commands from the UPC 80. The control unit 64 has a recording medium 64c on which a computer-readable program is recorded.

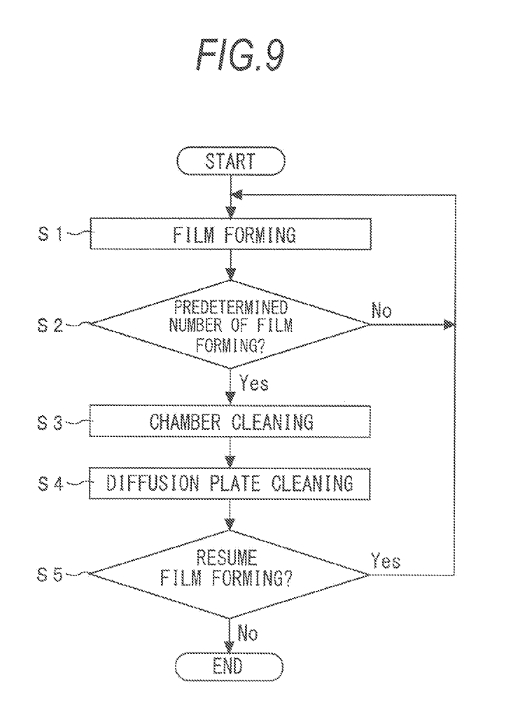

FIG. 9 is a flow chart for explaining the operation of the computer (master board 64b) in accordance with the program recorded on the recording medium 64c. First, in step S1, film forming processing is performed on a substrate while the substrate is mounted on the lower electrode 16. Film forming processing is performed while the gas diffuser gate valve 60 and the RPU gate valve 62 are closed as shown in FIG. 1. The MFC 52 is controlled in this state to supply a gas from the gas supply line 50 into the transport tube 40. The gas is diffused since part of the space in the transport tube 40 is blocked with the diffusion plate 60d. At this time, because of the existence of the diffusion plate 60d, the pressure P1 in a space 72 above the gas diffuser gate valve 60 becomes higher than the pressure P2 in a space 74 below the gas diffuser gate valve 60. With the increase in pressure P1, diffusion of the gas can be promoted.

The gas thus diffused enters the space 24 to be supplied to the substrate on the lower electrode 16 through the openings 20a of the upper electrode 20. A plasma is generated between the upper electrode 20 and the lower electrode 16 to progress film forming on the substrate. This process step is referred to as a film forming step.

In the film forming step, the program recorded on the recording medium 64c causes the master hoard 64b to control the MFC 52, thereby supplying the gas (material gas) from the gas supply line 50 into the transport tube 40. Simultaneously with or before this, the program causes the master board 64b to close the gas diffuser gate valve 60 and the RPU gate valve 62, thereby diffusing the material gas. It is important to realize, in the film forming step, a state where the pressure in the space 72 above the diffusion plate 60d in the transport tube 40 is higher than the pressure in the space 74 below the diffusion plate 60d.

Subsequently, in step S2, a check is made as to whether film forming has been performed a predetermined number of times, for example, whether the film forming step has been performed 100 times. If the film forming step has not been performed 100 times, film forming processing is again executed in step S1. If the film forming step has been performed 100 times, the process advances to step 83. This process step is executed by a processor in the UPC 80 or the module controller.

Step S3 is a chamber cleaning step for cleaning the chamber 12. In the chamber cleaning step, the program recorded on the recording medium 64c causes the master board 64b to open the gas diffuser gate valve 60 and the RPU gate valve 62. The program then causes the master board 64b to operate the remote plasma unit 42. That is, a cleaning gas is supplied into the transport tube 40 while the diffusion plate 60d and the blocking plate 62d are being set out of the transport tube 40. The cleaning gas is supplied from the remote plasma unit 42.

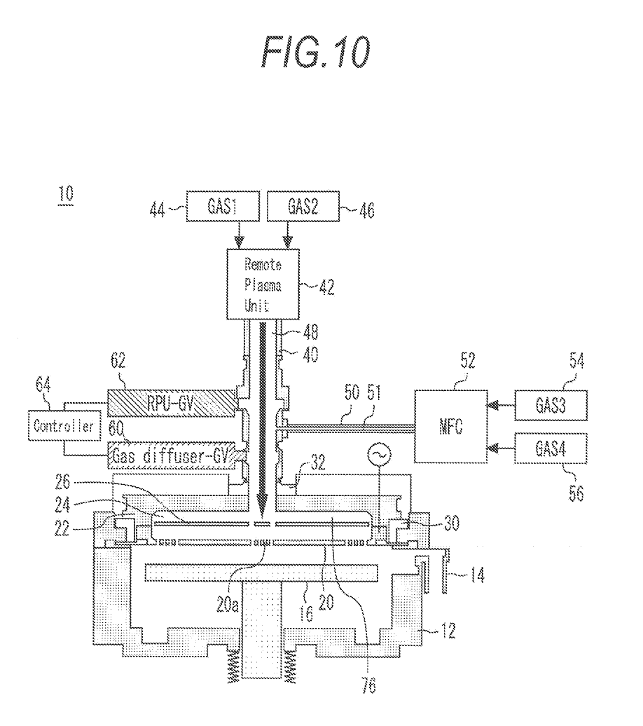

FIG. 10 is a sectional view of the film forming apparatus operating to execute the chamber cleaning step. The cleaning gas moves downward in the transport tube 40 without being impeded by the blocking plate 62d or the diffusion plate 60d. The direction of the flow of the cleaning gas at this time is the direction of the arrow in the passage 48 shown in FIG. 10. This cleaning as flows into the chamber 12 via the space 24 to clean the chamber 12. Therefore, no reduction in cleaning rate is caused due to the provision of the gas diffuser gate valve 60. If the pressure P1 in the space 72 is high during film forming, the material gas can solidify and accumulate easily on the diffusion plate 60d. In particular, in a case where a material gas of a low vapor pressure is used, the material gas can solidify and accumulate easily on the diffusion plate 60d. When the pressure P1 in the space 72 is about 50 times higher than the pressure P2 in the space 74, no solid accumulates on the diffusion plate 60d. However, if such a solid is produced and falls into the chamber 12 during film forming, the film forming quality is considerably reduced. In step 84, therefore, a diffusion plate cleaning step for cleaning the diffusion plate 60d is executed.

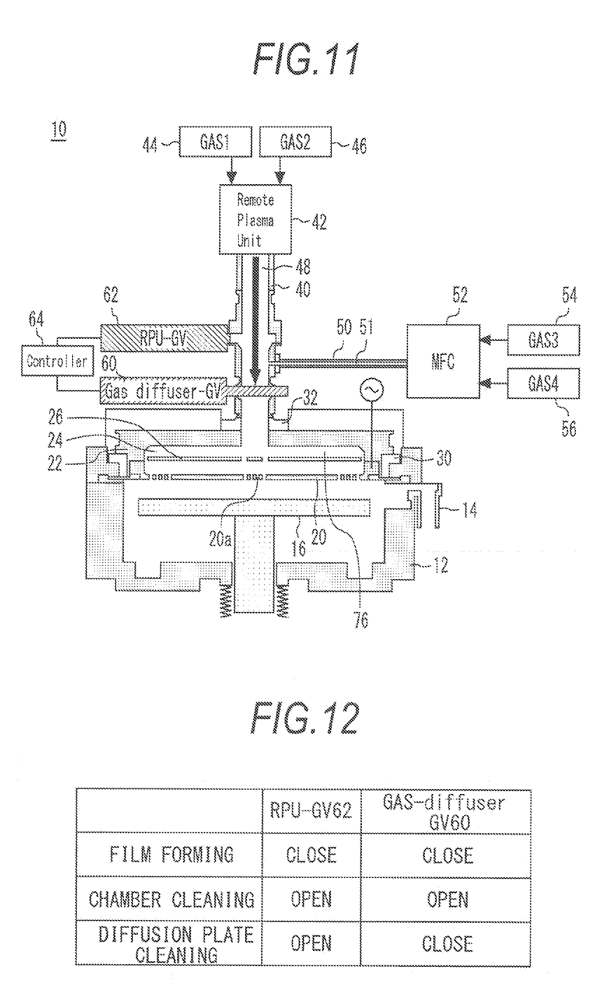

In the diffusion plate cleaning step, the program recorded on the recording medium 64c causes the master board 64b to close the gas diffuser gate valve 60 and open the IOU gate valve 62. FIG. 11 is a sectional view of the film forming apparatus operating to execute the diffusion plate cleaning step. A cleaning gas moves downward in the transport tube 40 without being impeded by the RPU gate valve 62. The direction of the flow of the cleaning gas at this time is the direction of the arrow in the passage 48 shown in FIG. 11. This cleaning gas is provided to the diffusion plate 60d to clean the diffusion plate 60d.

Thus, in the diffusion plate cleaning step, the cleaning gas is supplied into the transport tube 40 to clean the diffusion plate 60d while the diffusion plate 60d is set in the transport tube 40. Setting of the diffusion plate 60d in the route through which the cleaning gas passes enables cleaning of the diffusion plate 60d.

The process then advances to step S5. In step S5, film forming is again started if there is a need to again perform film forming. If there is no need for further film forming, the process ends.

FIG. 12 is a table showing combinations of opening/closing conditions of the gas diffuser gate valve 60 and the RPU gate valve 62 at the times of film forming, chamber cleaning and diffusion plate cleaning. Realizing these opening/closing conditions requires that the gas diffuser gate valve 60 be openable and closable.

It has been believed that the openings 20a of the upper electrode 20 have a certain effect on the promotion of diffusion of the material gas. A gas simulation made by the inventor of the present invention, however, has revealed that the state of diffusion of the material gas in the space above the upper electrode (RF plate) is an important factor in determining variation in gas concentration on the substrate. For example, in a case where a low-k film is formed by a plasma-enhanced chemical vapor deposition (PECVD) process, the film thickness profile of a 300 mm wafer depends on the distribution of the concentration of material gas before reaching the upper electrode. Therefore, if the material gas in the space above the upper electrode is sufficiently diffused and generally uniform in quality, variation in concentration of the material gas on the substrate can be limited. In recent years, because of a need to limit the in-plane thickness variation to 10 Å or less in some processes, it has become important to improve the film thickness uniformity in the substrate surface.

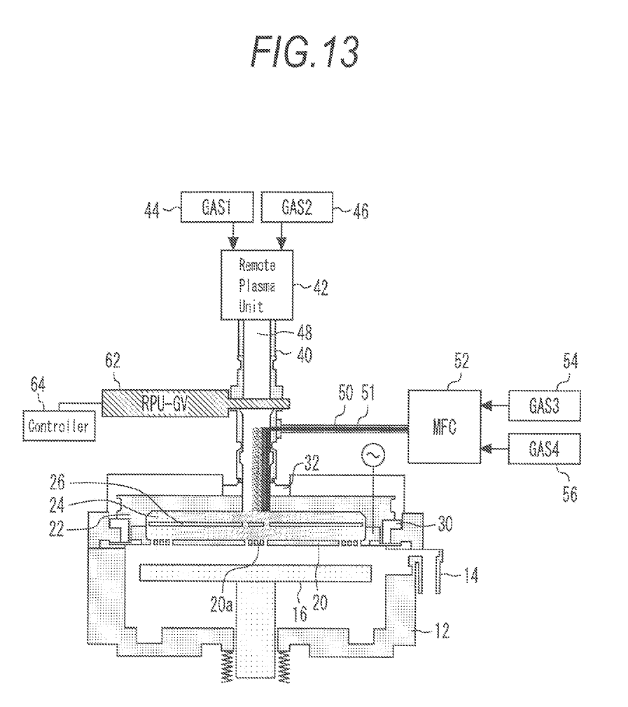

FIG. 13 is a sectional view of a film forming apparatus according to a comparative example. The film forming apparatus according to the comparative example differs from the film forming apparatus 10 according to the first embodiment in that the gas diffuser gate valve is not provided. In the comparative example, the material gas supplied into the space 24 above the upper electrode cannot be sufficiently diffused. FIG. 13 shows a state where the concentration of the material gas in the space 24 varies largely. In the film forming apparatus according to the comparative example, the film thickness uniformity in the substrate surface cannot be improved since the material gas is not sufficiently diffused in the space 24 above the upper electrode 20.

In contrast, in the first embodiment of the present invention, the provision of the diffusion plate 60d enables the material gas reaching the space 24 to be sufficiently diffused. Film forming with high film thickness uniformity in the substrate surface can therefore be carried out. Moreover, by executing the chamber cleaning step while the diffusion plate 60d is being kept in its retraction from the passage 48 of the transport tube 40, the cleaning gas can be supplied to the chamber 12 without being influenced by any contaminated condition of the diffusion plate 60d. Also, the diffusion plate 60d can be cleaned by being positioned in the cleaning gas passage.

The film forming apparatus, the recording medium and the film forming method according to the first embodiment of the present invention can be variously modified within such a scope that their features are not lost. For example, “the space above the upper electrode” is not limited to the space enclosed with the upper electrode 20 and the fixed top plate 22. “The space above the upper electrode” is not particularly specified if it is a space into which the gas is supplied from the transport tube 40. For example, “the space above the upper electrode” may be formed only by the upper electrode.

The remote plasma unit 42 and the MFC 52 may be replaced with each other. In such a case, the cleaning gas flowing generally in the horizontal direction is supplied into the transport tube 40, while the material gas flowing downward generally in the vertical direction is supplied into the transport tube 40. In the film forming step, the material gas can be diffused by opening the RPU gate valve and closing the gas diffuser gate valve. In the chamber cleaning step, the cleaning gas is supplied by maintaining the RPU gate valve in the closed state and the gas diffuser gate valve in the open state. In the diffusion plate cleaning step, both the RPU gate valve and the gas diffuser gate valve are closed.

The gas diffuser gate valve 60 and the RPU gate valve 62, described as separate parts, may be combined into one part. One part as a combination of these valves in such a case drives the two shafts 60b and 62b. The open-area percentage of the diffusion plate 60d can be changed as desired. When a material gas of a certain vapor pressure is used, however, there is a need to increase the open-area percentage to such an extent that the pressure P1 does not exceed the vapor pressure.

In ordinary cases, whether the material gas is flowing stably is monitored with the MFC 52. In such a case, a state where the pressure P1 is excessively high is recognized as an error. Also for this reason, one should he careful that the pressure P1 does not become excessively high.

Needless to say, the material gas is supplied from the two tubes in some cases. Two material gases may be simultaneously supplied or two material gases may be alternately supplied. If the apparatus is designed only to obtain the effect of the present invention, the RPU gate valve 62 may be removed. In such a case, the need for the operation to close the RPU gate valve in the film forming step and the diffusion plate cleaning step and the operation to open the RPU gate valve in the chamber cleaning step is eliminated.

These modifications can also be applied as desired to a film forming apparatus, a recording medium and a film forming method according to an embodiment described below. The film forming apparatus, recording medium and film forming method according to the embodiment described below will be described mainly with respect to points of difference from the first embodiment.

### Second Embodiment

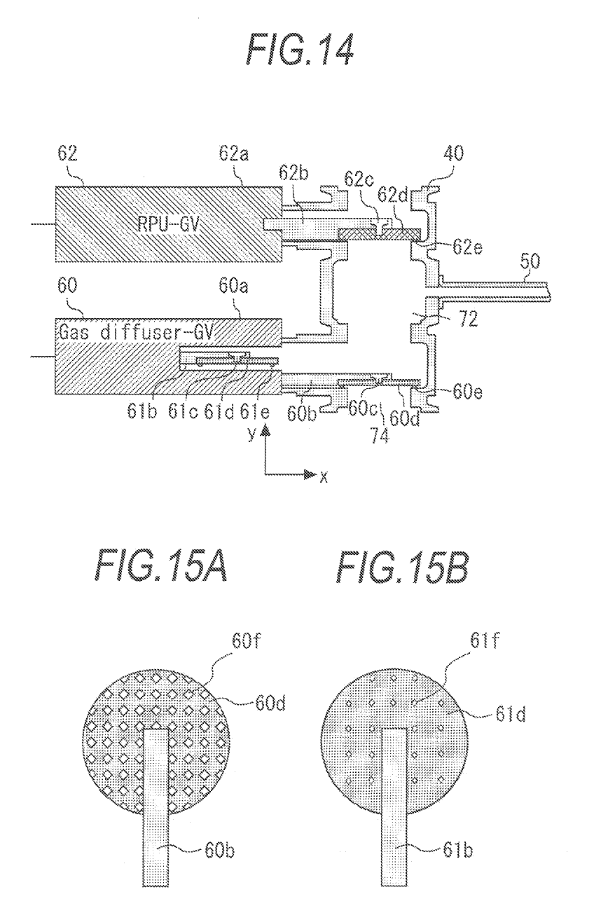

FIG. 14 is a sectional view of a gas diffuser gate valve 60 and other components of a film forming apparatus according to the second embodiment. This gas diffuser gate valve 60 has the diffusion plate 60d and an auxiliary diffusion plate 61d. The auxiliary diffusion plate 61d differs in open-area percentage from the diffusion plate 60d. FIG. 15A is a plan view of the diffusion plate 60d and FIG. 15B is a plan view of the auxiliary diffusion plate 61d. A plurality of holes 61f are formed in the auxiliary diffusion plate 61d. The open-area percentage of the auxiliary diffusion plate 61d is lower than that of the diffusion plate 60d.

Referring back to FIG. 14, a groove is formed in a lower surface of the auxiliary diffusion plate 61d, and an O-ring 61e is provided in the groove. A fixing part 61c is fixed on the auxiliary diffusion plate 61d. The auxiliary diffusion plate 61d is fixed to the shaft 61b by the fixing part 61c. The drive device 60a can cause each of the shafts 60b and 61b to move individually in an x-positive/negative direction and in a y-positive/negative direction. The drive device 60a puts one of the diffusion plate 60d and the auxiliary diffusion plate 61d in the transport tube 40 or retracts the one of the diffusion plate 60d and the auxiliary diffusion plate 61d from the transport tube 40.

The rate of flow of the gas supplied from the gas supply line 50 into the transport tube 40 is changed according to a film forming condition. When the gas flow rate is high, the pressure P1 in the space 72 above the gas diffuser gate valve 60 tends to be high. When the pressure P1 is excessively high, the material gas solidifies or an error output is issued from the MFC. Therefore, when the gas flow rate is high, the diffusion plate 60d having the higher open-area percentage is set in the transport tube 40 to prevent the pressure P1 from becoming excessively high.

When the gas flow rate is low, the pressure P1 in the space 72 above the gas diffuser gate valve 60 tends to be low. When the pressure P1 is excessively low, the material gas is not sufficiently diffused. Therefore, when the gas flow rate is low, the auxiliary diffusion plate 61d having the lower open-area percentage is set in the transport tube 40 to prevent the pressure P1 from becoming excessively low.

More specifically, the control unit 64 first obtains, from the recipe recorded in the MFC 52 or the UPC, information on the gas flow rate of the material gas in the gas supply line 50. The control unit 64 puts the diffusion plate 60d in the transport tube 40 when the gas flow rate is higher than a threshold value stored on the recording medium 64c. The control unit 64 puts the auxiliary diffusion plate 61d in the transport tube 40 when the gas flow rate is lower than the threshold value stored on the recording medium 64c.

Needless to say, three or more diffusion plates differing in open-area percentage may be prepared and suitable one of the diffusion plates may be selected according to the gas flow rate. Also, a diffusion plate capable of changing the open-area percentage may be used and a suitable open-area percentage may be set according to the gas flow rate.

According to the present invention, the material gas diffused with tile diffusion plate is supplied to the space above the upper electrode, and film forming with high film thickness uniformity in the substrate surface can therefore be carried out.

Obviously many modifications and variations of the present invention are possible in the light of the above teachings. It is therefore to be understood that within the scope of the appended claims the invention may be practiced otherwise than as specifically described.

20

What is claimed is:

1. A film forming apparatus comprising:
a lower electrode;
an upper electrode provided above and in opposition to the lower electrode and having a plurality of openings;
a transport tube which provides a passage extending generally in a vertical direction and connecting to a space above the upper electrode;
a gas supply line connected to a side surface of the transport tube and providing a passage communicating with a space in the transport tube; and
a gas diffuser gate valve connected to a portion of the side surface of the transport tube at a position lower in the vertical direction than the position at which the gas supply line is connected,
wherein the gas diffuser gate valve has a diffusion plate which blocks part of the space in the transport tube.

2. The film forming apparatus according to claim 1, wherein the gas diffuser gate valve has a drive device which puts the diffusion plate in the transport tube and retracts the diffusion plate from the transport tube.

3. The film forming apparatus according to claim 1, wherein a plurality of holes are formed in the diffusion plate.

4. The film forming apparatus according to claim 3, wherein a width of each of the plurality of holes at a lower surface of the diffusion plate is larger than its width at an upper surface of the diffusion plate.

5. The film forming apparatus according to claim 4, wherein each of the plurality of holes has a horn-like sectional shape.

6. The film forming apparatus according to claim 1, wherein the gas diffusion gate valve has an O-ring set in a groove in the diffusion plate, and the O-ring contacts the transport tube.

7. The film forming apparatus according to claim 1, further comprising an remote plasma unit gate valve connected to a portion of the side surface of the transport tube at a position higher in the vertical direction than the position at which the gas supply line is connected,
wherein the remote plasma unit gate valve has a blocking plate which blocks the space in the transport tube, and
wherein the remote plasma unit gate valve has a drive device which puts the blocking plate in the transport tube and retracts the blocking plate from the transport tube.

8. The film forming apparatus according to claim 1, wherein the gas diffuser gate valve has an auxiliary diffusion plate differing in open-area percentage from the diffusion plate; and
a drive device which puts one of the diffusion plate and the auxiliary diffusion plate in the transport tube and retracts the one of the diffusion plate and the auxiliary diffusion plate from the transport tube.

9. The film forming apparatus according to claim 1, further comprising a remote plasma unit connected to an upper end of the transport tube and arranged to provide a gas in a plasma state.

10. The film forming apparatus according to claim 1, further comprising a mass flow controller connected to the gas supply line.

11. The film forming apparatus according to claim 1, further comprising a fixed top plate provided above the upper electrode,
wherein the space above the upper electrode is a space enclosed with the upper electrode and the fixed top plate.

12. A computer-readable recording medium on which a program is recorded and which is readable with a computer, the program causing the computer to execute:
a film forming step including supplying a gas into a transport tube from a gas supply line connected to a side surface of the transport tube in which a passage extending generally in a vertical direction is provided, diffusing the gas by setting in the transport tube a diffusion plate blocking part of a space in the transport tube, and thereafter supplying the gas to a substrate on a lower electrode below an upper electrode through openings in the upper electrode;
a chamber cleaning step of cleaning a chamber surrounding the lower electrode by supplying a gas into the transport tube while setting the diffusion plate out of the transport tube; and
a diffusion plate cleaning step of cleaning the diffusion plate by supplying a gas into the transport tube while setting the diffusion plate in the transport tube.

13. The recording medium according to claim 12, wherein the film forming step further includes closing an remote plasma unit gate valve connected to a portion of the side surface of the transport tube at a position higher in the vertical direction than the position at which the gas supply line is connected, and
wherein each of the chamber cleaning step and the diffusion plate cleaning step further includes opening the remote plasma unit gate valve.

14. A film forming method comprising a film forming step including supplying a gas into a transport tube from a gas supply line connected to a side surface of the transport tube in which a passage extending generally in a vertical direction is provided, diffusing the gas by setting in the transport tube a diffusion plate blocking part of a space in the transport tube, and thereafter supplying the gas to a substrate on a lower electrode through openings in an upper electrode.

15. The film forming method according to claim 14, wherein, in the transport tube, pressure in a space above the diffusion plate is higher than pressure in a space below the diffusion plate.

16. The film forming method according to claim 14, further comprising:
a chamber cleaning step of cleaning a chamber surrounding the lower electrode by supplying a gas into the transport tube while setting the diffusion plate out of the transport tube; and
a diffusion plate cleaning step of cleaning the diffusion plate by supplying a gas into the transport tube while setting the diffusion plate in the transport tube.
